(19) United States
(12) Patent Application Publication
(10) Pub. No.: US 2026/0353621 A1
(43) Pub. Date: Nov. 5, 2026

(54) ELECTRICAL NOISE DISPERSION ON AN EXCAVATOR

(71) Applicant: Deere & Company, Moline, IL (US)

(72) Inventors: Lance R. Sherlock, Asbury, IA (US); Paul W. Burandt, Dubuque, IA (US); Lowell Melvin, Dubuque, IA (US)

(21) Appl. No.: 19/185,640

(22) Filed: Apr. 22, 2025

(51) Int. Cl. H05K 9/00; E02F 3/32; E02F 9/08; E02F 9/16; E02F 9/26

(52) U.S. Cl. CPC H05K 9/002; E02F 9/0858; E02F 9/16; E02F 9/26; H05K 9/0054; E02F 3/32

(57) ABSTRACT

A work machine includes an undercarriage, a main frame, and a boom assembly pivotally connected to the main frame. An operator's cabin is located on the main frame beside the boom assembly. The operator's cabin includes an electronics package located closer to a laterally inner side than to a laterally outer side of the operator's cabin. A baffle is mounted on the boom assembly such that the baffle is located between the electronics package and an adjacent side wall of the boom assembly when the boom assembly is in a pivotal position relative to the operator's cabin such that the adjacent side wall is located horizontally spaced from the electronics package, the baffle being configured to reduce reflection of ambient electromagnetic energy by the adjacent side wall of the boom assembly onto the electronics package.

### BACKGROUND OF THE DISCLOSURE

### Field of the Disclosure

The present disclosure relates to a system for reducing interference from ambient electromagnetic energy with an electronics package of a work machine.

### Description of the Prior Art

Electrical noise waves are an ever-increasing fact of life. Unfortunately, these waves can have a negative effect on electronic components and thus on overall performance and functionality. Modern vehicle displays are especially impacted. Many of the newer displays include a glass front for viewing or for interaction with a touchscreen. Depending upon the design of the internal electrical components, the electromagnetic waves can flow right through the glass and cause issues to the electronic display.

Accordingly, there is a need for improved designs to mitigate the impact of ambient electromagnetic energy on the electronics associated with the control station of such work machines.

### SUMMARY OF THE DISCLOSURE

We have observed that the adverse effects of ambient electromagnetic energy are a particular problem in the case of an excavator or similar work machine. An excavator has a unique machine layout and consistent system placement across the excavator industry. The steel boom is in the middle of the machine pointing forward. The boom is a large boxed generally rectangular cross-section steel structure. The excavator operator station is normally located directly to the left of the boom. Within the operator station the electronic display is normally located in the right front portion near the A-pillar where the front wall of the operator station joins the right side wall of the operator station. All of this placement results in the boom and the electronic display being within inches of each other. Electromagnetic energy may pass through the electronic display and then reflect off of the adjacent side wall of the boom and impinge on the electronic display a second time, potentially doubling the amount of electromagnetic energy which must be absorbed or dissipated by the electronic display. An electronic display so effected may reset itself on and off repeatedly due to electromagnetic energy encountering the control chip or circuit board of the display.

The present disclosure provides a system for reducing such interference from ambient electromagnetic energy by using a metal baffle mounted on the boom in an area that passes by the electronic display as the boom moves up and down. Such a baffle may disperse or re-direct the electromagnetic energy to reduce impingement of such electromagnetic energy on the electronic display.

In one aspect of the disclosure the work machine includes an undercarriage, a main frame mounted on the undercarriage to be pivotable about a vertical pivot axis relative to the undercarriage, and a boom assembly extending from the main frame, the boom assembly being pivotally connected to the main frame to pivot about a horizontal pivot axis. An operator's cabin is located on the main frame beside the boom assembly, the operator's cabin including a laterally inner side, a laterally outer side and a front, the laterally inner side of the operator's cabin being closer to the boom assembly than is the laterally outer side, the operator's cabin including an electronics package located closer to the laterally inner side than to the laterally outer side. A baffle is mounted on the boom assembly such that the baffle is located between the electronics package and an adjacent side wall of the boom assembly when the boom assembly is in a pivotal position relative to the operator's cabin such that the adjacent side wall is located horizontally spaced from the electronics package, the baffle being configured to reduce reflection of ambient electromagnetic energy by the adjacent side wall of the boom assembly onto the electronics package.

In another aspect of the disclosure a method of operating such a work machine includes steps of: providing a baffle mounted on an adjacent side wall of the boom assembly between the electronics package and the adjacent side wall of the boom assembly; and reducing reflection of ambient electromagnetic energy by the adjacent side wall of the boom assembly onto the electronics package by interaction of the baffle with the ambient electromagnetic energy either before or after the ambient electromagnetic energy is reflected by the adjacent side wall.

Numerous objects, features and advantages of the present disclosure will be readily apparent to those skilled in the art upon a review of following description in conjunction with the accompanying drawings.

### BRIEF DESCRIPTION OF THE DRAWINGS

FIG. 1 is a left side elevation view of an excavator of the present disclosure.

FIG. 2 is a schematic plan view of the excavator of FIG. 1.

FIG. 3 is a schematic left side elevation view of the lower portion of the boom of the excavator of FIG. 2, with a relative position of an electronics package in the operator's cabin indicated.

FIG. 4 is a view similar to FIG. 3, showing in shaded area an arcuate path of closest proximity of the electronics package to the adjacent side wall of the boom as the boom pivots past the electronics package.

FIG. 5 is a view similar to FIGS. 3 and 4 showing one location of a baffle covering most of the arcuate path of closest proximity.

FIG. 6 is an enlargement of the plan view of FIG. 2 in the area of the electronics package and the baffle.

FIG. 7 is a schematic perspective view of one form of baffle formed from a segment of expanded metal grating.

FIG. 8 is a schematic elevation view of a second form of baffle formed from diamond plate sheet metal.

FIG. 9 is a schematic perspective view of a third form of baffle formed from corrugated metal sheet.

FIG. 10 schematically illustrates a baffle mounted in an orientation non-parallel to the adjacent side wall of the boom.

### DETAILED DESCRIPTION

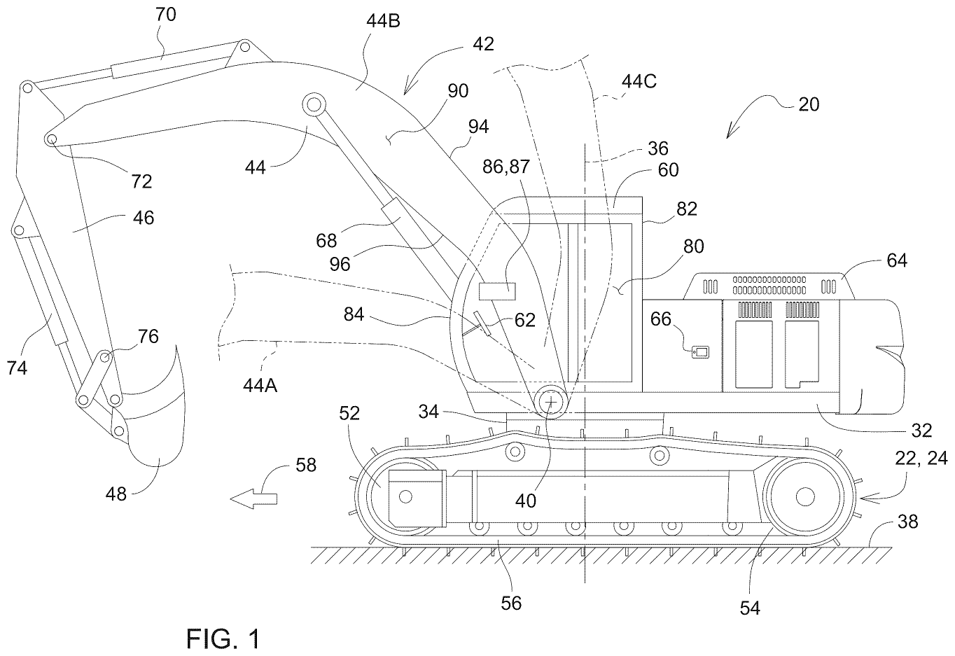

Referring now to the drawings and particularly to FIG. 1, a work machine is shown and generally designated by the number 20. FIG. 1 shows a tracked excavator machine 20. The systems disclosed herein are applicable to excavator machines and other work machines of the type having a boom assembly adjacent an operator's cab such as some forestry equipment like a knuckleboom loader. These machines may have tracked or wheeled ground engaging units supporting the undercarriage from the ground surface.

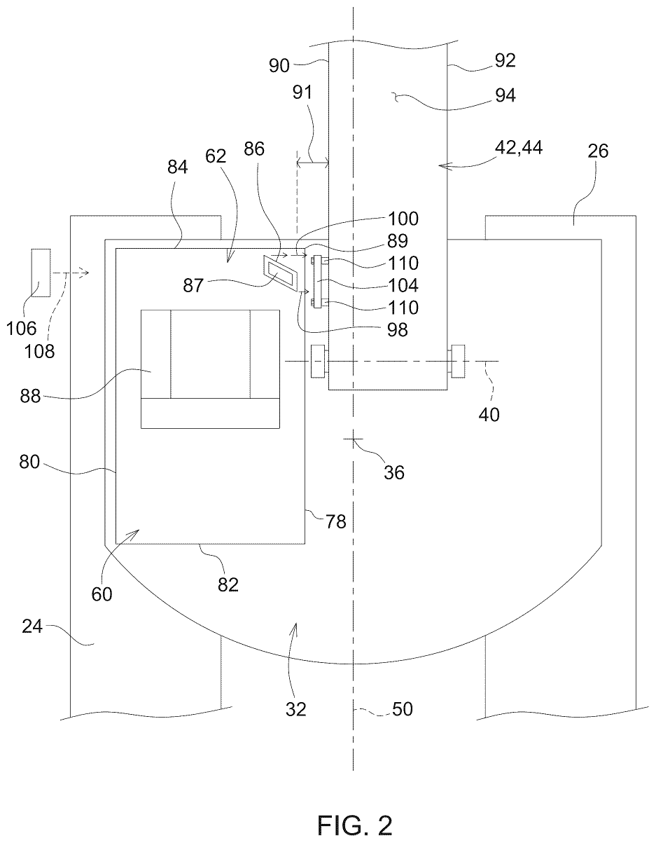

The work machine 20 is shown in side elevation assembled view in FIG. 1, and schematically in plan view in FIG. 2.

The work machine 20 includes an undercarriage 22 including first and second ground engaging units 24 and 26 in the form of tracked ground engaging units. Wheeled ground engaging units could also be used.

A main frame 32 is supported from the undercarriage 22 by a swing bearing 34 such that the main frame 32 is pivotable about a pivot axis 36 relative to the undercarriage. The pivot axis 36 is substantially vertical when a ground surface 38 engaged by the ground engaging units 24 and 26 is substantially horizontal. A swing hydraulic motor (not shown) is configured to pivot the main frame 32 on the swing bearing 34 about the pivot axis 36 relative to the undercarriage 22.

A boom assembly 42 includes a boom 44, an arm 46 pivotally connected to the boom 44, and a working tool 48. The boom 44 is pivotally attached to the main frame 32 to pivot about a generally horizontal axis 40 relative to the main frame 32. The working tool in this embodiment is an excavator shovel 48 which is pivotally connected to the arm 46. The boom assembly 42 extends from the main frame 32 along a working direction 50 of the boom assembly 42. The working direction 50 can also be described as a working direction of the boom 44.

In the embodiment of FIG. 1 the first and second ground engaging units 24 and 26 are tracked ground engaging units. Each of the tracked ground engaging units includes a front idler 52, a drive sprocket 54, and a track chain 56 extending around the front idler 52 and the drive sprocket 54. The travel motor of each tracked ground engaging unit 24 or 26 drives its respective drive sprocket 54. Each tracked ground engaging unit has a forward traveling direction 58 defined from the drive sprocket 54 toward the front idler 52. The forward traveling direction 58 of the tracked ground engaging units also defines a forward traveling direction 58 of the undercarriage 22 and thus of the work machine 20.

An operator's cab 60 may be located on the main frame 32. The operator's cab 60 and the boom assembly 42 may both be mounted on the main frame 32 so that the operator's cab 60 faces in the working direction 50 of the boom assembly. A control station 62 may be located in the operator's cab 60.

Also mounted on the main frame 32 is an engine 64 for powering the work machine 20. The engine 64 may be a diesel internal combustion engine. The engine 64 may also be any other suitable prime mover, including an electric motor. The engine 64 may drive a hydraulic pump 66 to provide hydraulic power to the various operating systems of the work machine 20.

A pair of boom actuators 68 on opposite sides of boom 44 raise and lower the boom assembly 42 and boom 44 about the horizontal pivot axis 40. An arm actuator 70 pivots the arm 46 relative to the boom 44 about an arm pivot 72. A bucket actuator 74 pivots the bucket 48 relative to arm 46 about bucket pivot 76.

As best seen in the schematic plan view of FIG. 2, the operator's cabin 60 is located on the main frame beside 32 the boom assembly 42. The operator's cabin 60 includes a laterally inner side 78, a laterally outer side 80, a rear 82 and a front 84. The laterally inner side 78 of the operator's cabin 60 is closer to the boom assembly 42 than is the laterally outer side 80. As noted, the operator's cabin 60 includes an operator's station 62 which may include an electronics package 86. Operator's station 62 may also include other electronics such as joysticks, or other operator input devices, and various informational readouts and the like. A driver's seat 88 may be located in the operator's cabin 60 facing the operator's station 62. The electronics package 86 may include a monitor 87. The electronics package 86 may be located near an A-pillar 89 joining the front 84 to the laterally inner side wall 78. In general, the electronics package 86 may be described as being located closer to the laterally inner side 78 than to the laterally outer side 80.

A variety of pivotal positions of the boom 44 about pivotal axis 40 are shown in FIG. 1. A lowermost position is shown in dashed lines and indicated as 44A. An intermediate position is shown in solid lines and indicated as 44B. An uppermost position is shown in dashed lines and indicated as 44C. The boom 44 and boom assembly 42 may be pivoted to any desired position by action of the boom actuators 68. As is apparent in viewing the multiple positions of the boom 44 shown in FIG. 1, there is an intermediate position similar to that indicated as 44B wherein the boom 44 is in close proximity to the electronics package 86 located in the operator's cabin 60.

As is schematically shown in FIGS. 1 and 2, the boom 44 is a box like structural member having a rectangular cross-section defined by a left side wall 90, a right side wall 92, a top wall 94 and a bottom wall 96. The left side wall 90 may further be described as an adjacent side wall 90 which is adjacent to the operator's cabin 60 and to the electronics package 86.

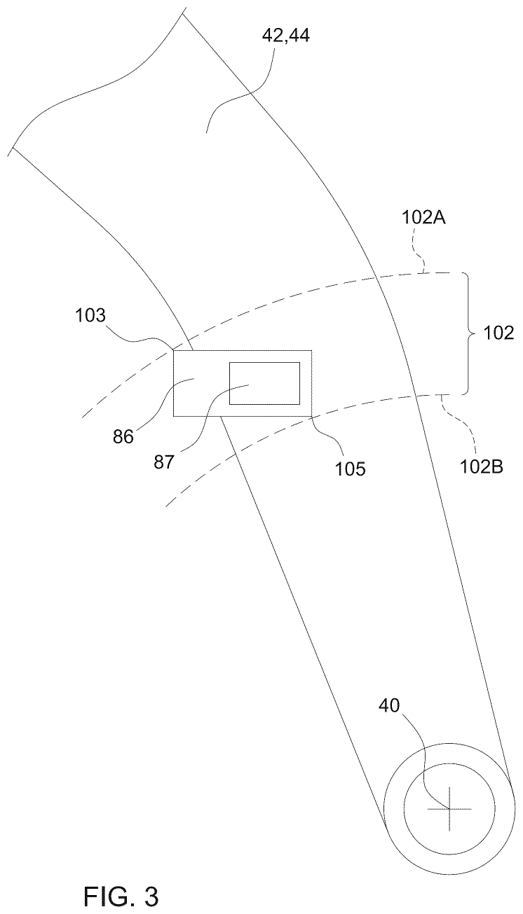

The electronics package 86 occupies a three-dimensional space, and a projection of that three-dimensional space occupied by the electronics package 86 toward the boom 44 in a direction parallel to the horizontal pivot axis 40 is represented by the dashed lines 98 and 100 seen in FIG. 2. That projection against the adjacent side wall 90 of the boom 44 will take the rectangular shape schematically shown in FIG. 1, and as the boom 44 pivots about axis 40 past the electronics package 86 that projected space will define an arcuate path 102 of closest proximity of the electronics package 86 to the adjacent side wall 90. The arcuate path 102 is best visualized in the enlarged schematic views of FIGS. 3-5. The arcuate path 102 may be bounded by an upper curve 102A and a lower curve 102B representing arcs about axis 40 which intersect with points 103 and 105 on the electronics package 86 which are furthest from and closest to the axis 40, respectively.

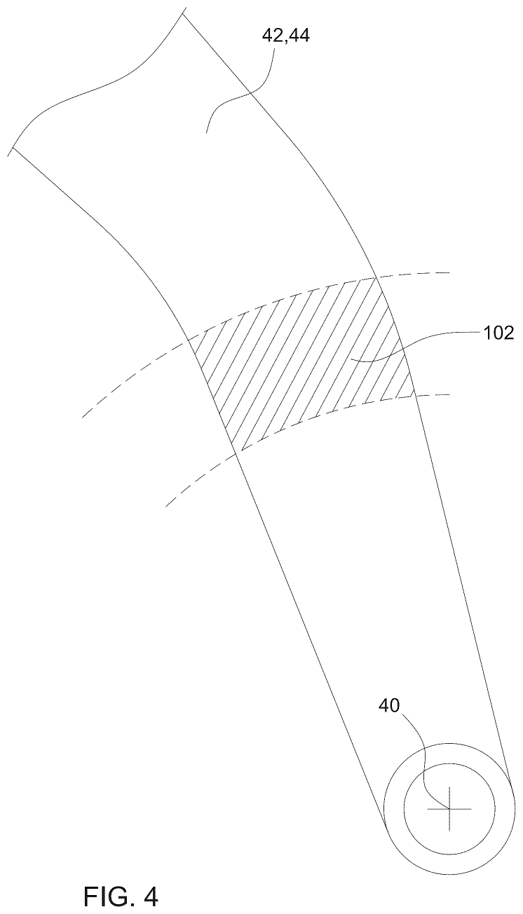

The arcuate path of closest proximity 102 is schematically represented in FIG. 4 as the shaded area identified as 102.

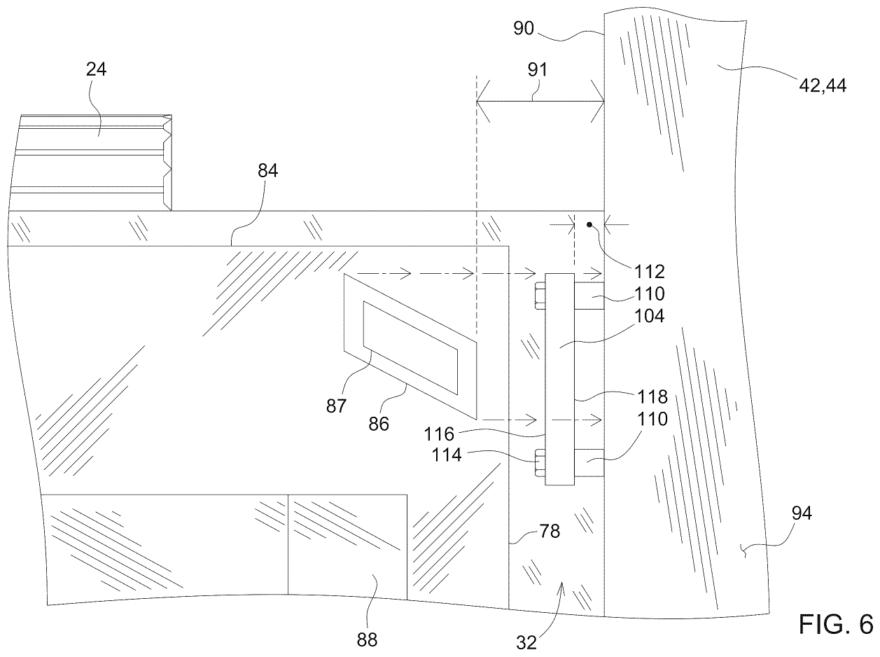

As schematically shown in FIG. 6, a portion of the electronics package 86 closest to the adjacent side wall 90 of the boom assembly 42 may be located within a distance 91 from the adjacent side wall 90 at a closest proximity of the electronics package 86 to the adjacent side wall 90. The distance 91 may be twelve inches or less. The distance 91 may be six inches or less.

It will be appreciated that in a typical modern work environment there may be many external sources of ambient electromagnetic energy in the vicinity of work machine 20 and particularly in the vicinity of the electronics package 86. Although many portions of the electronics package 86 may include shielding to protect the various components from such ambient electromagnetic energy, some components are still susceptible to damage from such ambient electromagnetic energy. For example, a monitor 87 of the electronics package 86 and components associated with the monitor 87 may be susceptible to electromagnetic energy entering through the transparent front screen of the monitor. In FIG. 2 an external source of ambient electromagnetic energy is schematically represented as 106, and electromagnetic energy from source 106 towards the electronics package 86 is schematically represented by dashed lines 108. Examples of such sources 106 of electromagnetic energy may include any electromagnetic transmitters of the type which must be licensed by the Federal Communications Commission (FCC). It will be appreciated that in actual practice the ambient electromagnetic energy 108 may impinge upon the electronics package 86 from all directions or any direction.

We have discovered that the negative effects of such ambient electromagnetic energy 108 on the electronics package 86 are particularly severe when the electronics package 86 is in a state of closest proximity to the adjacent side wall 90 of boom 44, such as in the position 44B shown in solid lines in FIG. 1. This increased susceptibility to damage is believed to be due to the electronics package 86 being effectively exposed twice to the ambient electromagnetic energy 108, once when the ambient electromagnetic energy 108 passes from the source 106 to the electronics package 86, and a second time when that ambient electromagnetic energy 108 reflects off of the adjacent side wall 90 of the boom assembly 42 and strikes the electronics package 86 a second time. The present disclosure is directed to various forms of baffling 104 which may reduce the effect of this ambient electromagnetic energy 108 on the electronics package 86.

As is schematically shown in FIGS. 2 and 6, a baffle 104 may be mounted on the boom 44 of boom assembly 42 such that the baffle 104 is located between the electronics package 86 and the adjacent side wall 90 of the boom assembly 42 when the boom assembly 42 is in a pivotal position relative to the operator's cabin 60 such that the adjacent side wall 90 is located horizontally spaced from the electronics package as schematically shown in FIG. 1 in the position 44B. The baffle 104 is configured to reduce reflection of ambient electromagnetic energy 108 by the adjacent side wall 90 of the boom assembly 42 onto the electronics package 86.

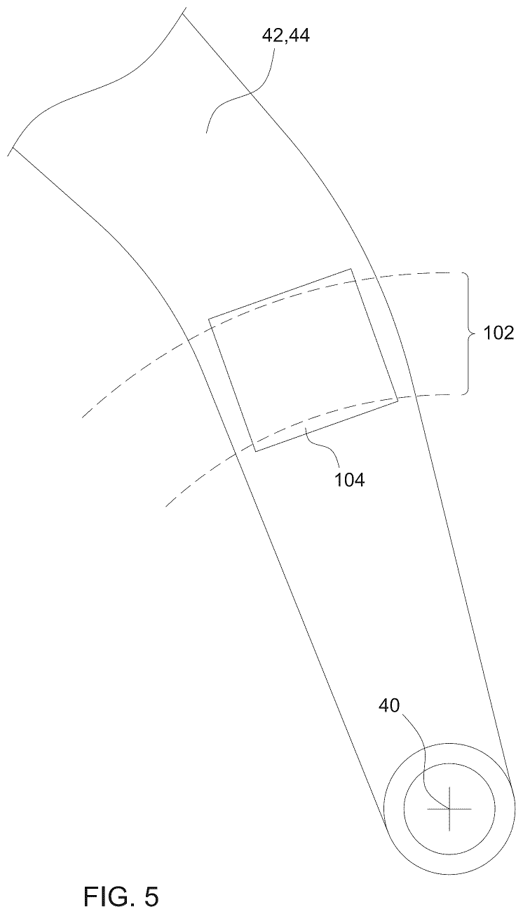

The baffle 104 may be mounted on the adjacent side wall 90 of boom 44 so that the baffle 108 covers at least a portion of the arcuate path of closest proximity 102. The baffle 104 preferably covers a majority of the arcuate path of closest proximity 102 as shown schematically in FIG. 5, and the baffle 104 may cover the entire area of the arcuate path of closest proximity 102. The baffle 104 may cover a surface area of at least 2.0 square feet as viewed in FIG. 5 in a direction parallel to the horizontal pivot axis 40.

The boom 44 may include a plurality of bosses 110 protruding from the adjacent side wall 90, and the baffle 104 may be bolted to the bosses 110 with bolts 114 or by welding, or by any other suitable technique. The baffle 104 may be attached to the bosses 110 such that a standoff distance 112 exists between the baffle 104 and the adjacent side wall 90 of the boom 44. The standoff distance 112 may for example be in a range of from about 0.5 inch to about 3.0 inch, and more preferably in a range of from about 1.0 inch to about 2.0 inch.

The baffle 104 may include a baffle outer side 116 facing away from the adjacent side wall 90 and a baffle inner side 118 facing toward the adjacent side wall 90.

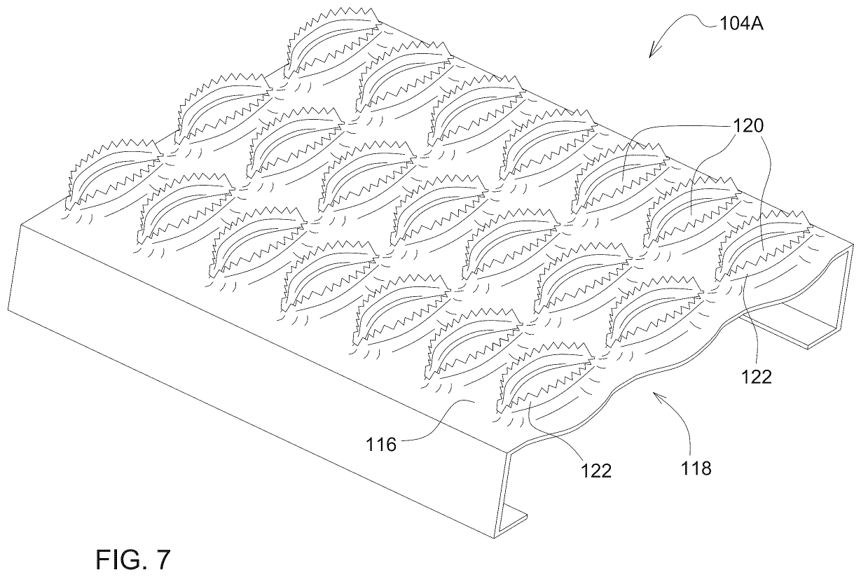

In one embodiment the baffle 104 may be formed from a segment of expanded metal grating as shown in FIG. 7 and designated as 104A. The baffle 104A includes a plurality of openings 120 extending from the baffle outer side 116 to the baffle inner side 118 such that the ambient electromagnetic energy 108 in part passes through the openings 120 and then reflects off of the adjacent side wall 90 and the reflected electromagnetic energy in part impinges on the baffle inner side 118. The baffle 104A also includes a plurality of raised angled surfaces 122 oriented non-parallel to the adjacent side wall 90 such that the ambient electromagnetic energy 108 moving towards the adjacent side wall 90 in a direction parallel to the horizontal pivot axis 40 is reflected away from the adjacent side wall 90 rather than being allowed to impinge on the adjacent side wall 90 and reflect back to the electronics package 86. Other electromagnetic energy 108 coming from other directions may be similarly deflected away from the electronics package 86 either before or after striking the adjacent side wall 90.

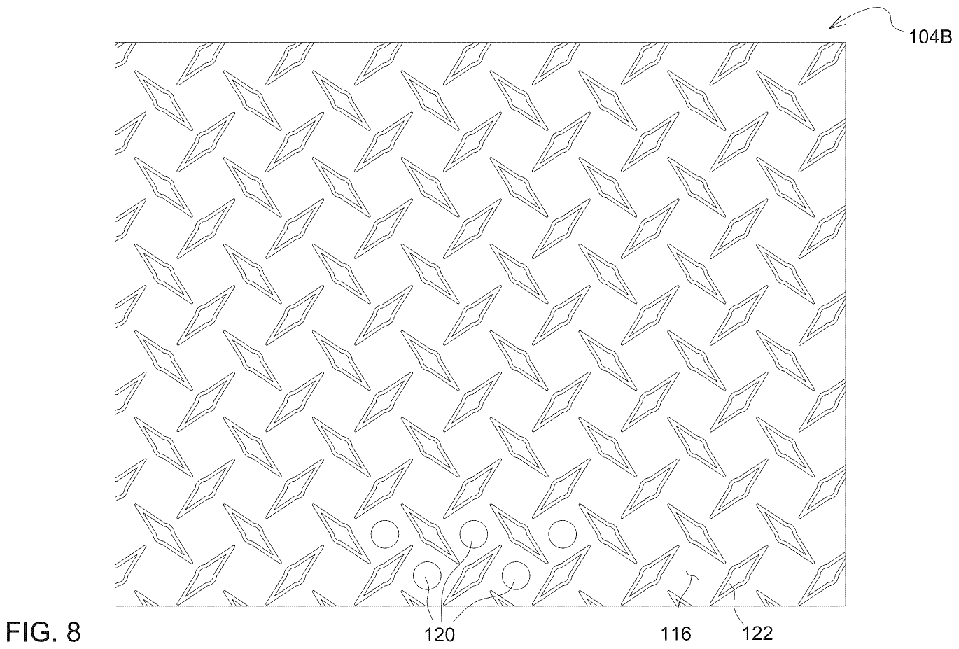

In another embodiment the baffle 104 may be formed from a sheet of diamond plate as shown in FIG. 8 and designated as 104B. Such diamond plate may be a solid plate with a pattern of raised “diamond” shaped structures raised angled surfaces 122, in the form of raised diamond shapes 122, with portions of the diamond shapes 122 oriented non-parallel to the adjacent side wall 90 such that the ambient electromagnetic energy 108 moving towards the adjacent side wall 90 in a direction parallel to the horizontal pivot axis 40 is reflected away from the adjacent side wall 90 rather than being allowed to impinge on the adjacent side wall 90 and reflect back to the electronics package 86. The baffle 104B may also include openings 120 extending from the baffle outer side 116 to the baffle inner side 118 such that the ambient electromagnetic energy 108 in part passes through the openings 120 and then reflects off of the adjacent side wall 90 and the reflected electromagnetic energy in part impinges on the baffle inner side 118. Other electromagnetic energy 108 coming from other directions may be similarly deflected away from the electronics package 86 either before or after striking the adjacent side wall 90.

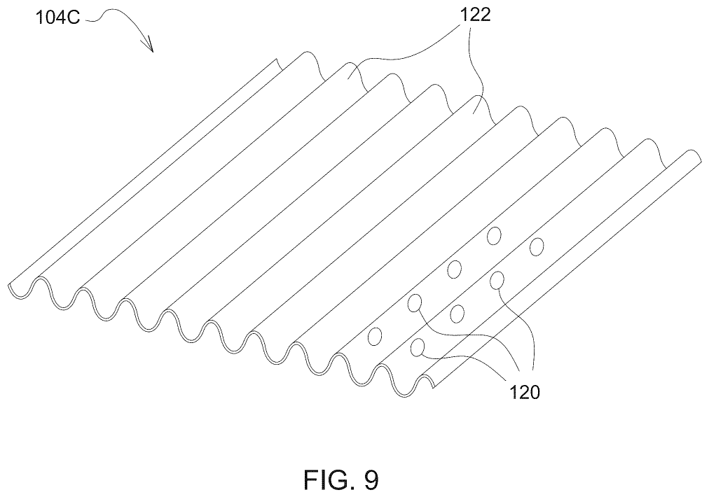

In another embodiment the baffle 104 may be formed from a sheet of corrugated metal as shown in FIG. 9 and designated as 104C. Such a corrugated metal sheet baffle 104C may include raised angled surfaces 122, in the form of corrugations 122 oriented non-parallel to the adjacent side wall 90 such that the ambient electromagnetic energy 108 moving towards the adjacent side wall 90 in a direction parallel to the horizontal pivot axis 40 is reflected away from the adjacent side wall 90 rather than being allowed to impinge on the adjacent side wall 90 and reflect back to the electronics package 86. The baffle 104C may also include openings 120 extending from the baffle outer side 116 to the baffle inner side 118 such that the ambient electromagnetic energy 108 in part passes through the openings 120 and then reflects off of the adjacent side wall 90 and the reflected electromagnetic energy in part impinges on the baffle inner side 118. Other electromagnetic energy 108 coming from other directions may be similarly deflected away from the electronics package 86 either before or after striking the adjacent side wall 90.

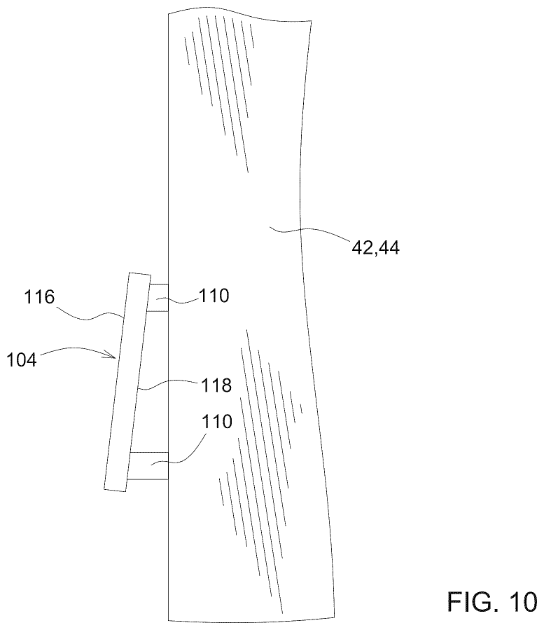

When using a baffle such as baffle 104B formed from a sheet of plate material the entire baffle 104 may be placed in an orientation non-parallel to the adjacent side wall 90 by making the supporting bosses 110 on one end of the baffle 104B shorter than the supporting bosses 110 on an opposite end of the baffle 104B. The other baffle types 104A and 104C may similarly use supporting bosses 110 of different lengths to place the entire baffle in an orientation non-parallel to the adjacent side wall 90, as is schematically shown in FIG. 10.

Any of the baffles 104A, 104B or 104C may be made of a metal material, which may be steel or a steel alloy, or aluminum or an aluminum alloy, or any other suitable metal which can reflect or block transmission of electromagnetic energy.

A method of reducing interference from ambient electromagnetic energy with the electronics package 86 of the work machine 20 may include steps of;
providing the baffle 104 mounted on the adjacent side wall 90 of the boom assembly 42 between the electronics package 86 and the adjacent side wall 90 of the boom assembly 42; and
reducing reflection of ambient electromagnetic energy by the adjacent side wall 90 of the boom assembly 42 onto the electronics package 86 by interaction of the baffle 104 with the ambient electromagnetic energy 108 either before or after the ambient electromagnetic energy 108 is reflected by the adjacent side wall 90.

The reducing step may include reducing reflection of the ambient electromagnetic energy 108 by the adjacent side wall 90 of the boom assembly 42 onto the electronics package 86 by interaction of the baffle 104 with the ambient electromagnetic energy 108 both before and after the ambient electromagnetic energy 108 is reflected by the adjacent side wall 90.

The reducing step may include reflecting at least a portion of the ambient electromagnetic energy 108 away from both the adjacent side wall 90 and the electronics package 86 before the ambient electromagnetic energy 108 impinges on the adjacent side wall 90.

The reducing step may include passing at least a portion of the ambient electromagnetic energy 108 through a plurality of openings 120 in the baffle 104 so that the ambient electromagnetic energy 108 which passes through the plurality of openings 120 reflects from the adjacent side wall 90 and impinges on a baffle inner side 118 facing the adjacent side wall 90 of the boom assembly 42 instead of being reflected onto the electronics package 86.

The method may further include moving the baffle 104 with the boom assembly 42 relative to the operator's cabin 60 and the electronics package 86 when the boom assembly 42 is pivoted relative to the operator's cabin 60, and providing a changing portion of the baffle 104 directly between the electronics package 86 and a closest point on the adjacent side wall 90 of the boom assembly 42 as the boom assembly 42 is pivoted relative to the operator's cabin 60.

Thus, it is seen that the apparatus and methods of the embodiments disclosed herein readily achieve the ends and advantages mentioned as well as those inherent therein. While certain preferred embodiments have been illustrated and described for purposes of the present disclosure, numerous changes in the arrangement and construction of parts and steps may be made by those skilled in the art, which changes are encompassed within the scope and spirit of the present invention as defined by the appended claims.

What is claimed is:

1. A work machine, comprising:
an undercarriage;
a main frame mounted on the undercarriage to be pivotable about a vertical pivot axis relative to the undercarriage;
a boom assembly extending from the main frame, the boom assembly being pivotally connected to the main frame to pivot about a horizontal pivot axis;
an operator's cabin located on the main frame beside the boom assembly, the operator's cabin including a laterally inner side, a laterally outer side and a front, the laterally inner side of the operator's cabin being closer to the boom assembly than is the laterally outer side, the operator's cabin including an electronics package located closer to the laterally inner side than to the laterally outer side; and
a baffle mounted on the boom assembly such that the baffle is located between the electronics package and an adjacent side wall of the boom assembly when the boom assembly is in a pivotal position relative to the operator's cabin such that the adjacent side wall is located horizontally spaced from the electronics package, the baffle being configured to reduce reflection of ambient electromagnetic energy by the adjacent side wall of the boom assembly onto the electronics package.

2. The work machine of claim 1, wherein:
a projection of a space occupied by the electronics package toward the boom assembly in a direction parallel to the horizontal pivot axis defines an arcuate path of closest proximity on the adjacent side wall of the boom assembly as the boom assembly pivots relative to the operator's cabin past the electronics package; and
the baffle is mounted such that the baffle covers at least a portion of the arcuate path of closest proximity.

3. The work machine of claim 2, wherein:
the baffle covers a majority of the arcuate path of closest proximity.

4. The work machine of claim 1, wherein:
the baffle is made of metal and is mounted such that a standoff distance exists between the baffle and the adjacent side wall of the boom assembly.

5. The work machine of claim 4, wherein:
the standoff distance is in a range of 0.5 inch to 3.0 inch.

6. The work machine of claim 4, wherein:
the baffle includes a baffle outer side facing away from the adjacent side wall and a baffle inner side facing toward the adjacent side wall, and the baffle includes a plurality of openings extending from the baffle outer side to the baffle inner side such that the ambient electromagnetic energy in part passes through the openings and then reflects off of the adjacent side wall and the reflected electromagnetic energy in part impinges on the baffle inner side.

7. The work machine of claim 6, wherein:
the baffle outer side includes one or more surfaces oriented non-parallel to the adjacent side wall of the boom assembly such that the ambient electromagnetic energy moving towards the adjacent side wall in a direction parallel to the horizontal pivot axis is reflected away from the adjacent side wall and away from the electronics package.

8. The work machine of claim 4, wherein:
the baffle includes a baffle outer side facing away from the adjacent side wall and a baffle inner side facing toward the adjacent side wall, and the baffle outer side includes one or more surfaces oriented non-parallel to the adjacent side wall of the boom assembly such that the ambient electromagnetic energy moving towards the adjacent side wall in a direction parallel to the horizontal pivot axis is reflected away from the adjacent side wall and away from the electronics package.

9. The work machine of claim 1, wherein:
a portion of the electronics package closest to the adjacent side wall of the boom assembly is within no more than 12 inches from the adjacent side wall at a closest proximity of the electronics package to the adjacent side wall.

10. The work machine of claim 1, wherein:
the baffle is made of steel or a steel alloy.

11. The work machine of claim 1, wherein:
the baffle is made of aluminum or an aluminum alloy.

12. The work machine of claim 1, wherein:
the baffle covers a surface area of at least 2.0 square feet as viewed in a direction parallel to the horizontal pivot axis.

13. The work machine of claim 1, wherein:
the work machine is an excavator.

14. The work machine of claim 1, wherein:
the electronics package includes a monitor.

15. The work machine of claim 1, wherein:
the boom assembly includes a plurality of bosses protruding from the adjacent side wall; and
the baffle is bolted to the bosses.

16. A method of reducing interference from ambient electromagnetic energy with an electronics package of a work machine, the work machine including an undercarriage, a main frame mounted on the undercarriage to be pivotable about a vertical pivot axis relative to the undercarriage, a boom assembly extending from the main frame, the boom assembly being pivotally connected to the main frame to pivot about a horizontal pivot axis, an operator's cabin located on the main frame beside the boom assembly, the operator's cabin including a laterally inner side, a laterally outer side and a front, the laterally inner side of the operator's cabin being closer to the boom assembly than is the laterally outer side, the operator's cabin including the electronics package located closer to the laterally inner side than to the laterally outer side, the method comprising:
providing a baffle mounted on an adjacent side wall of the boom assembly between the electronics package and the adjacent side wall of the boom assembly ; and
reducing reflection of ambient electromagnetic energy by the adjacent side wall of the boom assembly onto the electronics package by interaction of the baffle with the ambient electromagnetic energy either before or after the ambient electromagnetic energy is reflected by the adjacent side wall.

17. The method of claim 16, wherein:
the reducing includes reducing reflection of ambient electromagnetic energy by the adjacent side wall of the boom assembly onto the electronics package by interaction of the baffle with the ambient electromagnetic energy both before and after the ambient electromagnetic energy is reflected by the adjacent side wall.

18. The method of claim 16 wherein:
the reducing includes reflecting at least a portion of the ambient electromagnetic energy away from both the adjacent side wall and the electronics package before the ambient electromagnetic energy impinges on the adjacent side wall.

19. The method of claim 16, wherein:
the reducing includes passing at least a portion of the ambient electromagnetic energy through a plurality of openings in the baffle so that the ambient electromagnetic energy which passes through the plurality of openings reflects from the adjacent side wall and impinges on a baffle inner side facing the adjacent side wall of the boom assembly instead of being reflected onto the electronics package.

20. The method of claim 16, further comprising:
moving the baffle with the boom assembly relative to the operator's cabin and the electronics package when the boom assembly is pivoted relative to the operator's cabin, and providing a changing portion of the baffle directly between the electronics package and a closest point on the adjacent side wall of the boom assembly as the boom assembly is pivoted relative to the operator's cabin.
